(19) United States
(12) Patent Application Publication
(10) Pub. No.: US 2007/0279152 A1
(43) Pub. Date: Dec. 6, 2007

(54) THIN FILM PIEZOELECTRIC RESONATOR AND METHOD OF MANUFACTURING SAME

(75) Inventor: Yoshihisa Kawamura, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/756,958

(22) Filed: Jun. 1, 2007

(30) Foreign Application Priority Data
Jun. 5, 2006 (JP) 2006-156259

(51) Int. Cl. H03H 9/58

(52) U.S. Cl. 333/187; 333/189

(57) ABSTRACT

A thin film piezoelectric resonator includes: a substrate having an opening portion which passes through from a top surface to a bottom surface of the substrate, and an aperture which is provided distant from the opening portion; a resonance section having a lower electrode provided on the opening portion of the substrate, a piezoelectric film provided on the lower electrode and an upper electrode opposed to the lower electrode across the piezoelectric film; a cover layer; and a resin layer provided on the cover layer. The cover layer covers the resonance section through a cavity which is formed above the upper electrode. The cavity is connected to the aperture.

### CROSS-REFERENCE TO RELATED APPLICATIONS

This application is based upon and claims the benefit of priority from the prior Japanese Patent Application No. 2006-156259, filed on Jun. 5, 2006; the entire contents of which are incorporated herein by reference.

### BACKGROUND OF THE INVENTION

1. Field of the Invention

This invention relates to a thin film piezoelectric resonator and a method of manufacturing the same.

2. Background Art

A thin film piezoelectric resonator using vertical resonance in thickness of a piezoelectric film is designated as FBAR (Film Bulk Acoustic Resonator) or BAW (Bulk Acoustic Wave) element or the like. The thin film piezoelectric resonator has an extremely small device size, and high excitation efficiency and a sharp resonant characteristic are obtained in a region above GHz zone, therefore, it is a promising technology for application to an RF filter and a voltage controlled oscillator for mobile radio transmission or the like.

A method of manufacturing the thin film piezoelectric resonator is proposed (JP2004-222244A). This method comprises steps of formation of a resonance section on a wafer, forming a sacrifice layer on the wafer, depositing a dielectric film of thickness of about 1.5 μm on the sacrifice layer, opening partially the dielectric film, and removing the sacrifice layer through opening portions.

In the method of manufacturing the thin film piezoelectric resonator, a general purpose process used for formation of an integrated circuit can be applied, therefore the thin film piezoelectric resonator can be manufactured at a low price. However, as the above thin film is broken because of stress relaxation associated with removal of the above sacrifice layer, a problem due to lack of mechanical strength is easy to occur.

### SUMMARY OF THE INVENTION

According to an aspect of the invention, there is provided a thin film piezoelectric resonator including: a substrate having an opening portion which passes through from a top surface to a bottom surface of the substrate, and an aperture which is provided distant from the opening portion; a resonance section having a lower electrode provided on the opening portion of the substrate, a piezoelectric film provided on the lower electrode and an upper electrode opposed to the lower electrode across the piezoelectric film; a cover layer covering the resonance section through a cavity which is formed above the upper electrode; and a resin layer provided on the cover layer, the cavity being connected to the aperture.

According to another aspect of the invention, there is provided a thin film piezoelectric resonator including: a substrate having an opening portion which passes through from a top surface to a bottom surface of the substrate, and an aperture which is provided distant from the opening portion; a resonance section having a lower electrode provided on the opening portion of the substrate, a piezoelectric film provided on the lower electrode and an upper electrode opposed to the lower electrode across the piezoelectric film; a cover layer covering the resonance section through a cavity which is formed above the upper electrode; and a resin layer provided on the cover layer, the cavity being connected to the aperture, and the cavity having a ceiling portion being convex upward.

According to another aspect of the invention, there is provided a method of manufacturing a thin film piezoelectric resonator, including: forming a resonance section by providing a lower electrode, a piezoelectric film and an upper electrode in this order on a substrate; forming a pattern of a sacrifice layer selectively on the upper electrode; forming a cover layer covering the resonance section including the sacrifice layer; forming a resin layer on the cover layer; forming an opening portion which passes through the substrate below the lower electrode and an aperture which arrives at the sacrifice layer by passing through the substrate; and forming a cavity above the upper electrode by introducing an etchant through the aperture.

### BRIEF DESCRIPTION OF THE DRAWINGS

FIG. 1 shows a top view of a high frequency filter using a thin film piezoelectric resonator according to the embodiment of the invention.

FIG. 2 shows an A-A cross section of the high frequency filter in FIG. 1.

FIG. 3 shows a B-B cross section of the high frequency filter in FIG. 1.

FIG. 4 shows a high frequency filter circuit using the thin film piezoelectric resonator according to the embodiment of the invention.

FIG. 5 shows a configuration example of the plane pattern in FIG. 4.

FIG. 6 shows a process of manufacturing a high frequency filter using a thin film piezoelectric resonator according to the embodiment of the invention.

FIG. 7 shows a process of manufacturing a high frequency filter using a thin film piezoelectric resonator according to the embodiment of the invention.

FIG. 8 shows a top view of the high frequency filter circuit using the thin film piezoelectric resonator according to the embodiment of the invention.

FIG. 9 shows an A-A cross section of the high frequency filter in FIG. 8.

FIG. 10 shows a top view of the high frequency filter circuit using the thin film piezoelectric resonator according to the embodiment of the invention.

FIG. 11 shows an A-A cross section of the high frequency filter in FIG. 10.

FIG. 12 shows a top view of the high frequency filter circuit using the thin film piezoelectric resonator according to the embodiment of the invention.

FIG. 13 shows an A-A cross section of the high frequency filter in FIG. 12.

FIG. 14 shows a top view of the high frequency filter circuit using the thin film piezoelectric resonator according to the embodiment of the invention.

FIG. 15 shows an A-A cross section of the high frequency filter in FIG. 14.

FIG. 16 shows a top view of the high frequency filter circuit using the thin film piezoelectric resonator according to the embodiment of the invention.

FIG. 17 shows an A-A cross section of the high frequency filter in FIG. 16.

FIG. 18 shows a top view of the high frequency filter circuit using the thin film piezoelectric resonator according to the embodiment of the invention.

FIG. 19 shows an A-A cross section of the high frequency filter in FIG. 17.

FIG. 20 shows a top view of the high frequency filter circuit using the thin film piezoelectric resonator according to the embodiment of the invention.

FIG. 21 shows an A-A cross section of the high frequency filter in FIG. 20.

FIG. 22 shows an A-A cross section of the high frequency filter in FIG. 20.

FIG. 23 shows a top view of the high frequency filter circuit using the thin film piezoelectric resonator according to the embodiment of the invention.

FIG. 24 shows an A-A cross section of the high frequency filter in FIG. 23.

FIG. 25 shows a top view of the high frequency filter circuit using the thin film piezoelectric resonator according to the embodiment of the invention.

FIG. 26 shows an A-A cross section of the high frequency filter in FIG. 25.

FIG. 27 shows a bottom view of the high frequency filter in FIG. 25.

FIG. 28 shows a B-B cross section of the high frequency filter in FIG. 25.

FIG. 29 shows a top view of the high frequency filter circuit using the thin film piezoelectric resonator according to the embodiment of the invention.

FIG. 30 shows a B-B cross section of the high frequency filter in FIG. 29.

FIG. 31 shows a cross section of the high frequency filter circuit using the thin film piezoelectric resonator according to the embodiment of the invention.

FIG. 32 shows a cross section enlarging a portion of a high frequency filter using a thin film piezoelectric resonator according to a first modification example of the embodiment of the invention.

FIG. 33 shows a process of manufacturing the high frequency filter in FIG. 32.

FIG. 34 shows a cross section enlarging a portion of a high frequency filter using a thin film piezoelectric resonator according to a second modification example of the embodiment of the invention.

FIG. 35 shows a process of manufacturing the high frequency filter in FIG. 34.

FIG. 36 shows a process of manufacturing the high frequency filter in FIG. 34.

### DETAILED DESCRIPTION

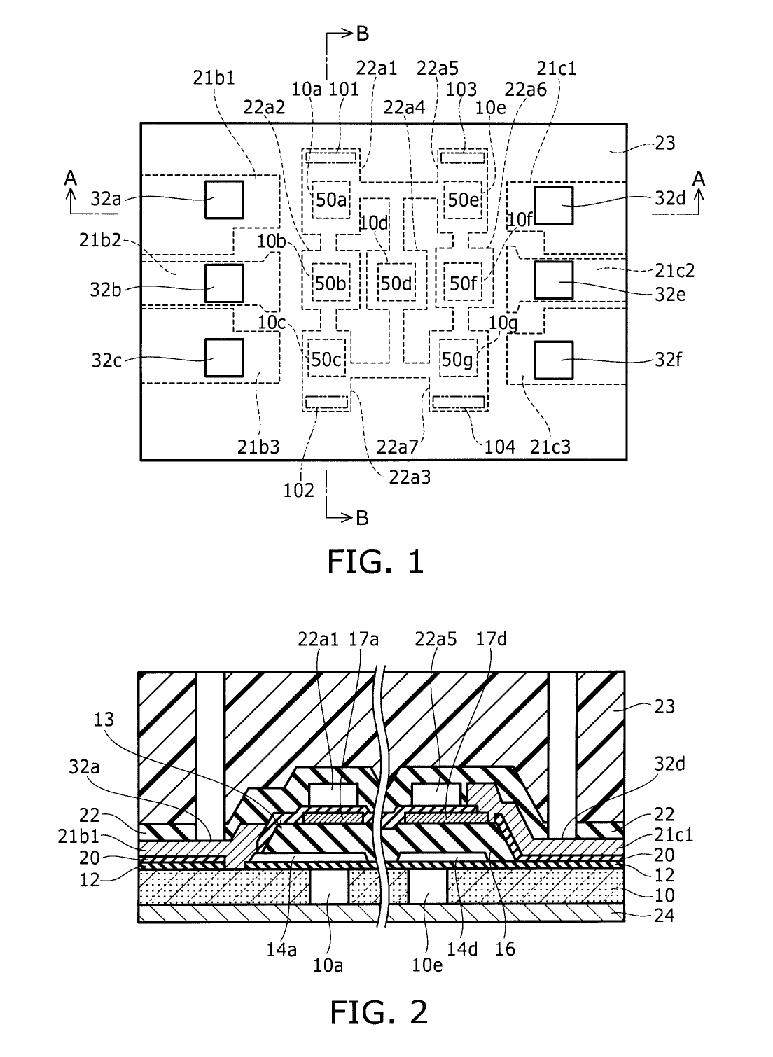

Embodiments of the invention will now be described with illustration of a filter as an application example, however the embodiments of the invention are not limited to the filter, but may be other circuits such as applications or the like to an oscillator circuit or the like. Furthermore, they may be a single thin film piezoelectric resonator as a discrete element. Moreover, a filter configuration shown in FIG. 1 and FIG. 2 is an example and is not limited to FIG. 1 and FIG. 2. There are various connecting stage numbers of elements and connecting patterns of thin film resonators. By the way, elements having the same function or a similar function in figures are marked with the same or similar reference numerals and not described in detail.

FIG. 4 illustrates a configuration having seven thin film piezoelectric resonators 50a, 50b, 50c, 50d, 50e, 50f and 50g as a high frequency filter according to the embodiment of the invention.

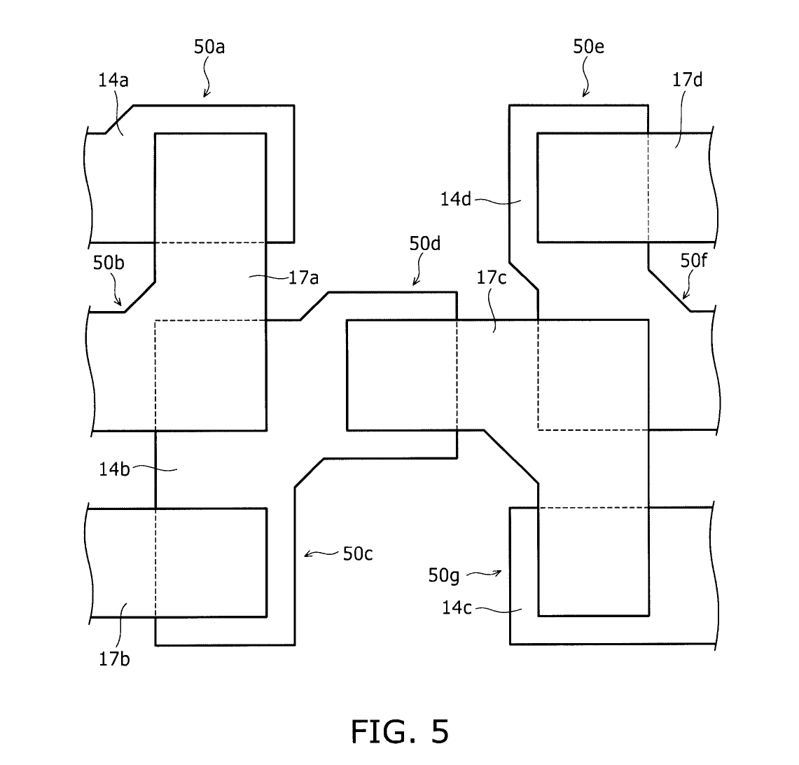

Seven thin film piezoelectric resonators 50a to 50g are arranged so as to connect in series or parallel as shown in FIG. 5. The high frequency filter is a 3.5 stages ladder type filter which thin film piezoelectric resonators 50b, 50d and 50f are series resonator and thin film piezoelectric resonators 50a, 50c, 50e and 50g are parallel resonators.

As shown in FIG. 4, in the high frequency filter an upper electrode wiring 17a electrically connected to one terminal 201 of an input port Pin is patterned as a common upper electrode to the thin film piezoelectric resonator 50a and the thin film piezoelectric resonator 50b. A lower electrode wiring 14a electrically connected to the other terminal 202 of the input port Pin serves as the lower electrode of the thin film piezoelectric resonator 50a.

A lower electrode wiring 14b of the thin film piezoelectric resonator 50b is patterned as the common lower electrode to the thin film piezoelectric resonator 50c and the 50d, respectively. An upper electrode wiring 17b electrically connected to the other terminal 202 of the input port Pin in the thin film piezoelectric resonator 50c is patterned. And the lower electrode wiring 14b is disposed as the pattern of the common lower electrode to the thin film piezoelectric resonators 50b, 50c and 50d.

An upper electrode wiring 17c is patterned as the upper electrode common to three thin film piezoelectric resonators 50d, 50f and 50g in the thin film piezoelectric resonators 50d, 50f and 50g. A lower electrode wiring 14c electrically connected to one terminal 204 of an output terminal Pout is patterned in the thin film piezoelectric resonator 50g. A lower electrode wiring 14d electrically connected to the other terminal 203 of the output terminal Pout is patterned as the common lower electrode to the thin film piezoelectric resonator 50f and the thin film piezoelectric resonator 50e. An upper electrode wiring 17d electrically connected to the one terminal 204 of the output terminal Pout is patterned in the thin film piezoelectric resonator 50e.

FIG. 1 is a top view of the high frequency filter according to the embodiment of the invention, and opening portions 10a, 10b, 10c, 10d, 10e, 10f and 10g correspondingly provided in seven thin film piezoelectric resonators 50a to 50g, respectively and apertures 101, 102, 103 and 104 distant from opening portions 10a to 10g are shown.

FIG. 2 is an A-A cross section of the thin film piezoelectric resonator 50a and the thin film piezoelectric resonator 50e of the high frequency filter shown in FIG. 1, and a substrate 10 comprising the opening portions 10a and 10e and a resonator section 13 provided on the substrate 10 are shown, however as shown by a break line at a center portion a part between the opening portion 10a and the opening portion 10e is omitted. While graphic display is omitted, other thin film piezoelectric resonators 50b, 50c, 50d, 50f and 50g also have the almost similar cross sectional structure. The resonance section 13 of the thin film piezoelectric resonators 50a and 50e provide the lower electrode wirings 14a and 14d on the opening portions 10a and 10e of the substrate 10, a piezoelectric film 16 on the lower electrode wirings 14a and 14d and the upper electrode wirings 17a and 17d facing the lower electrode wirings 14a and 14d across the piezoelectric film 16. Furthermore, the high frequency filter has a sealing substrate 24 under the substrate 10, a protecting film 12 provided on the substrate 10, a passivation film 20 provided on the protecting film 12, extracting wirings 21b1 and 21c1 provided on a part of the passivation film 20, a cover layer 22 provided on the resonance section 13 and a resin layer 23 provided on the cover layer 22. The cover layer 22 provides cavities 22a1 and 22a5 above the upper electrode wirings 17a and 17d of the thin film piezoelectric resonators 50a and 50e (while graphic display is omitted, other thin film piezoelectric resonators 50b, 50c, 50d, 50f and 50g are also almost similar).

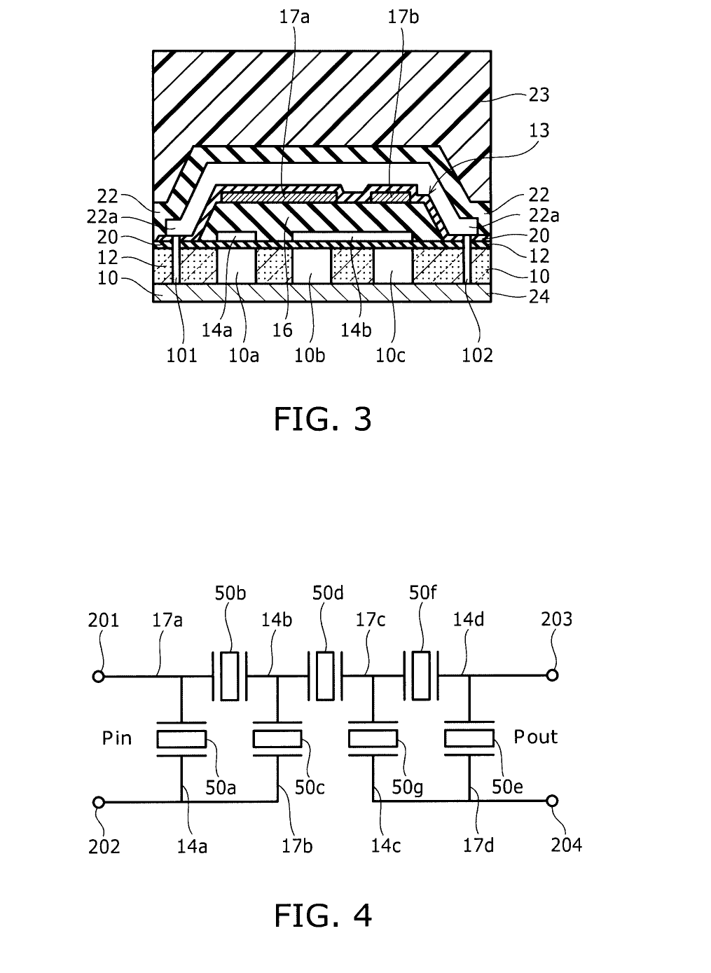

FIG. 3 is a B-B cross section cutting the thin film piezoelectric resonators 50a, 50b, 50c of the high frequency filter shown in FIG. 1, the apertures 101, 102 arriving at the cavity 22 through the protect film 12 and the passivation film 20 from the back side of the substrate 10 so as to avoid the resonance section 13 (while graphic display is omitted, a cross section cutting the thin film piezoelectric resonators 50e, 50f, 50g indicates a cross sectional structure having almost similar apertures.).

As shown in FIG. 2, in the high frequency filter, the extracting wiring 21b1 is connected to the lower electrode wiring 14a and the extracting wiring 21c1 is connected to the upper electrode wiring 17d. Furthermore, FIG. 1 shows an extracting wiring 21b2 connected to the upper electrode wiring 17a (See FIG. 5), an extracting wiring 21b3 connected to the upper wiring electrode 17b (See FIG. 5), an extracting wiring 21c2 connected to the lower electrode wiring 14d (See FIG. 5) and an extracting wiring 21c3 connected to the lower electrode wiring 14c (See FIG. 5). Moreover, the extracting wirings 21b1, 21b2, 21b3, 21c1, 21c2 and 21c3 provide electrode pad portions 32a, 32b, 32c, 32d, 32e and 32f, respectively and are connected to outer electrodes (not shown).

A semiconductor substrate such as silicon (Si) or the like is used as the sealing substrate 24 and the substrate 10. Materials with high chemical resistance such as Aluminum nitride (AlN) or the like are used in terms of protecting the resonance section 13 during etching. Polymer with high thermal resistance such as polyimide and permanent photo resist or the like can be used as a resin layer 23.

Thin film piezoelectric resonators 50a and 50e shown in the cross section of FIG. 2 will be described with paying attention to them. A high frequency signal applied between the lower electrode wirings 14a, 14d and the upper electrode wirings 17a, 17d excites a bulk acoustic wave and causes resonance in the piezoelectric film 16 of the resonance section 13. For example, the high frequency signal in a range of GHz zone is applied between the lower electrode wirings 14a, 14d and the upper electrode wirings 17a, 17d, and then the piezoelectric film 16 of the resonance section 13 resonates. In order to achieve an excellent resonance characteristic of the resonance section 13, an AlN film or ZnO film having excellent uniformity of film thickness and film quality including crystalline orientation or the like is used as the piezoelectric film 16. Aluminum (Al) and stacked metal films such as tantalum aluminum (TaAl) or the like, refractory metals such as molybdenum (Mo), tungsten (W) and titanium (Ti) or the like, and metal compound including refractory metals are used for the lower electrode wirings 14a, 14d. Metal of Al or the like, refractory metals of Mo, W, Ti or the like and metal compound including refractory metals are used for the upper electrode wirings (also similar as to other thin film piezoelectric resonators 50b, 50c, 50d, 50f and 50g).

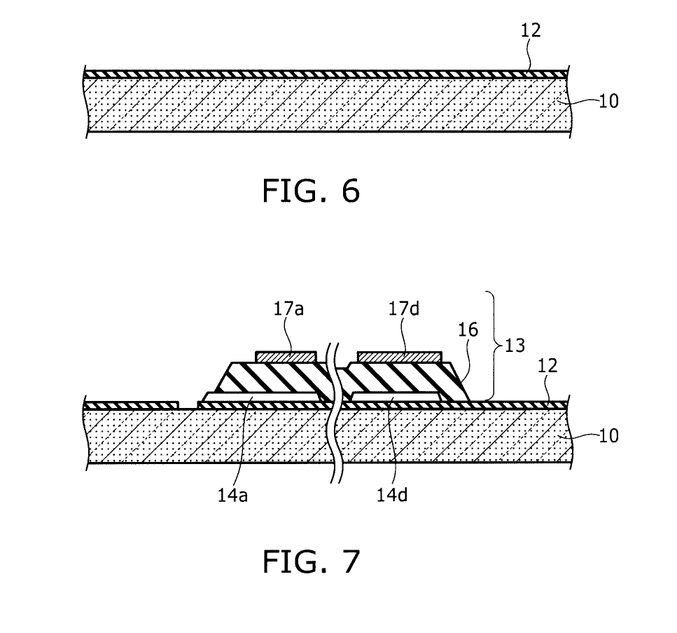

A method of manufacturing a high frequency filter using the thin film piezoelectric resonator according to the embodiment of the invention will be described with reference to FIG. 6 to FIG. 31 while mainly paying attention to the thin film piezoelectric resonators 50a and 50e shown in the cross sections:

(a) As shown in FIG. 6, a protect film 12 is formed on a substrate 10 of Si substrate or the like by thermal oxidation or the like. And then as shown in FIG. 7, a resonance section 13 is formed on the substrate 10. Specifically a metal film of Mo or the like is deposited on the protect film 12 by a direct current (DC) magnetron sputtering or the like, thereafter the metal film is removed by photo lithography and reactive ion etching (RIE) or the like, and patterns of lower electrode wirings 14a, 14d are formed. Next, an AlN film is deposited on the substrate 10 patterned with the lower electrode wirings 14a, 14d by high frequency (RF) magnetron sputtering or the like, the AlN film is selectively removed by photo lithography and RIE or the like using chloride gas, and patterns of a piezoelectric film 16 are formed on a surface of the lower electrode wirings 14a, 14d. Furthermore, a metal film of Al or the like is deposited on the substrate 10 with the patterned piezoelectric film 16 by DC magnetron sputtering or the like, thereafter the metal film is selectively removed by photo lithography and wet etching or the like using non-oxidizing acid, for example hydrochloric acid or the like, and patterns of upper electrode wirings 17a, 17d facing the lower electrode wirings 14a, 14d so as to sandwich the patterns of the piezoelectric film 16 are formed (also similar as to patterns of other lower electrode wirings 14b, 14c and upper electrode wirings 17b, 17c not shown in the cross section of FIG. 7 as is clear from FIG. 5.).

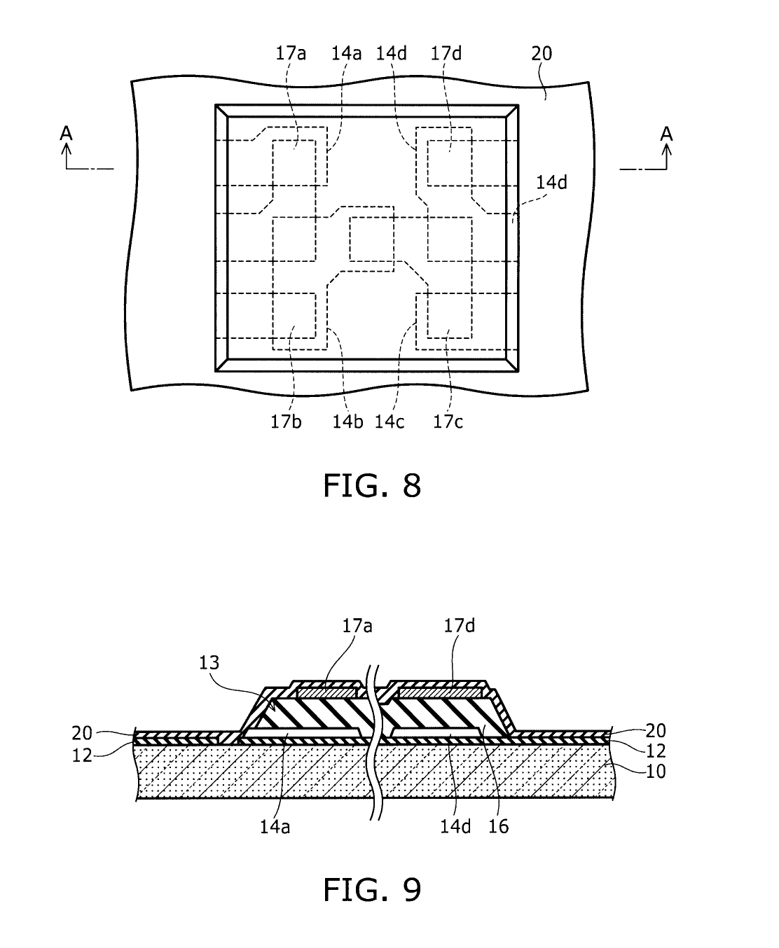

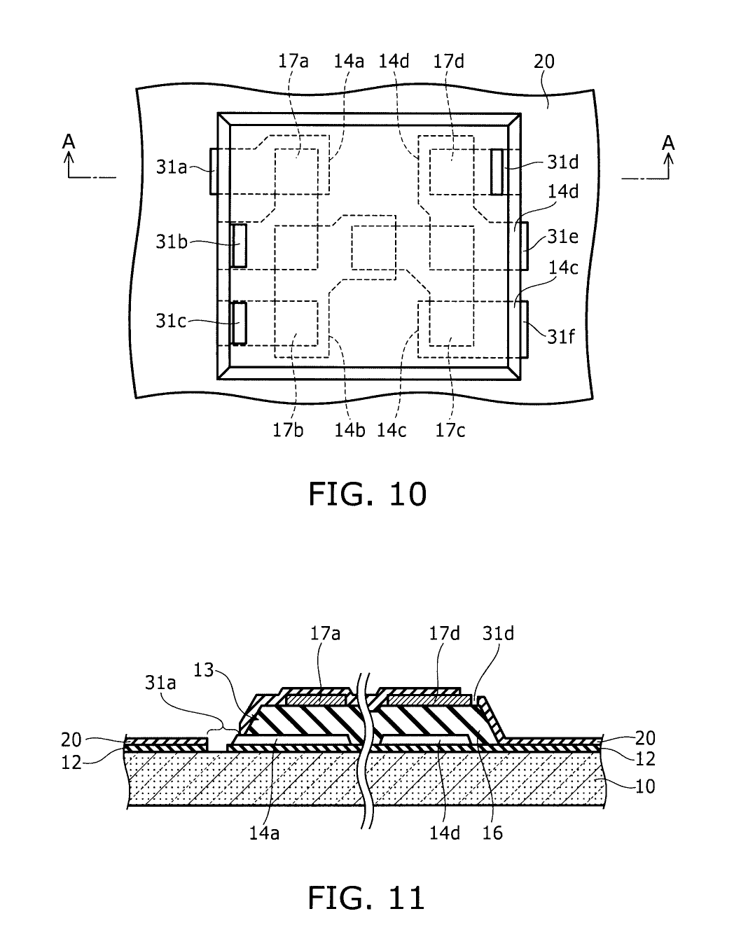

(b) As shown in FIG. 8 and FIG. 9, a passivation film 20 made of silicon nitride (Si₃N₄) film is deposited all over the substrate 10 using chemical vapor deposition (CVD) or the like so as to cover the upper electrode wirings 17a, 17d. And then, as shown in FIG. 11, a part of the passivation film 20 is removed using photo lithography and RIE or the like, and electrode extracting portions 31a, 31d shown by solid lines in the figure are opened with respect to the lower electrode wiring 14a and the upper electrode wiring 17d, respectively. While graphic display of the cross section is omitted, electrode extracting portions 31b, 31c, 31e, 31f are also opened with respect to the upper electrode wirings 17a, 17b and the lower electrode wirings 14d, 14c as shown in FIG. 10.

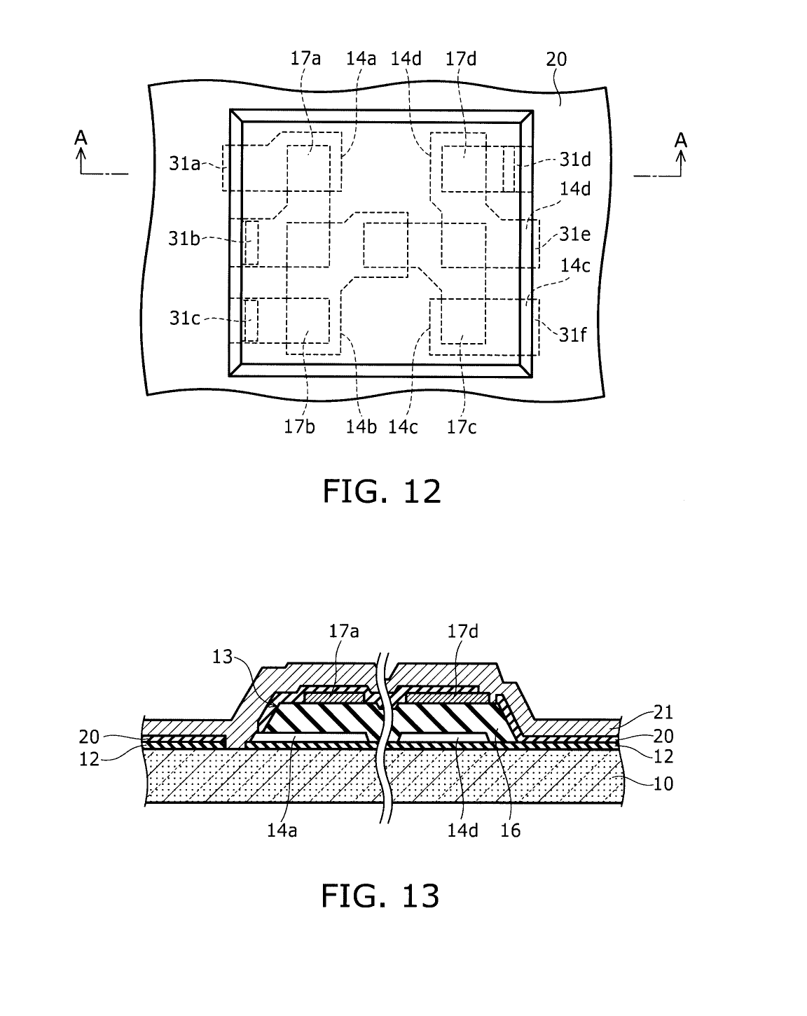

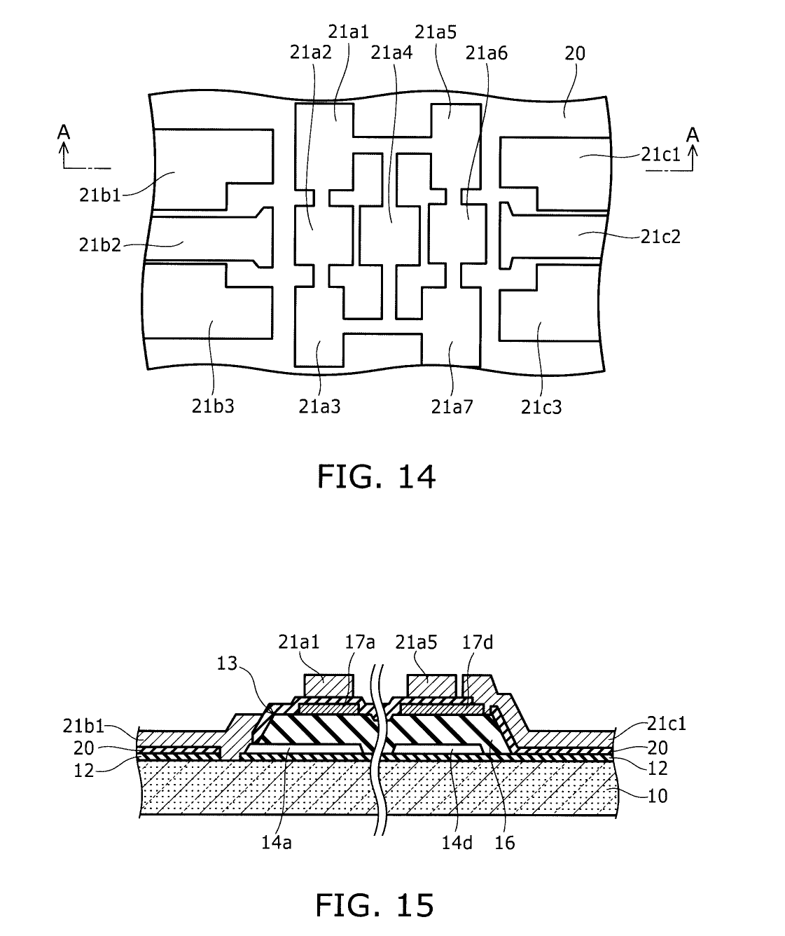

(c) As shown in FIG. 12 and FIG. 13, a metal film 21 of Al or the like is deposited on the passivation film 20 of about 1 μm by sputtering or the like. And then, a part of the metal film 21 is removed by dry etching or the like using gas including chlorine (Cl), and as shown in FIG. 15, patterns of an extracting wiring 21b1 connected to the lower electrode wiring 14a, an extracting wiring 21c1 connected to the upper electrode wiring 17d and sacrifice layers 21a1, 21a5 are formed. While graphic display of the cross section is omitted, as shown in FIG. 14, patterns of an extracting wiring 21b2 connected to the upper electrode wiring 17a, an extracting wiring 21b3 connected to the upper electrode wiring 17b, an extracting wiring 21c2 connected to the lower electrode wiring 14d and an extracting wiring 21c3 connected to the lower electrode wiring 14c are formed.

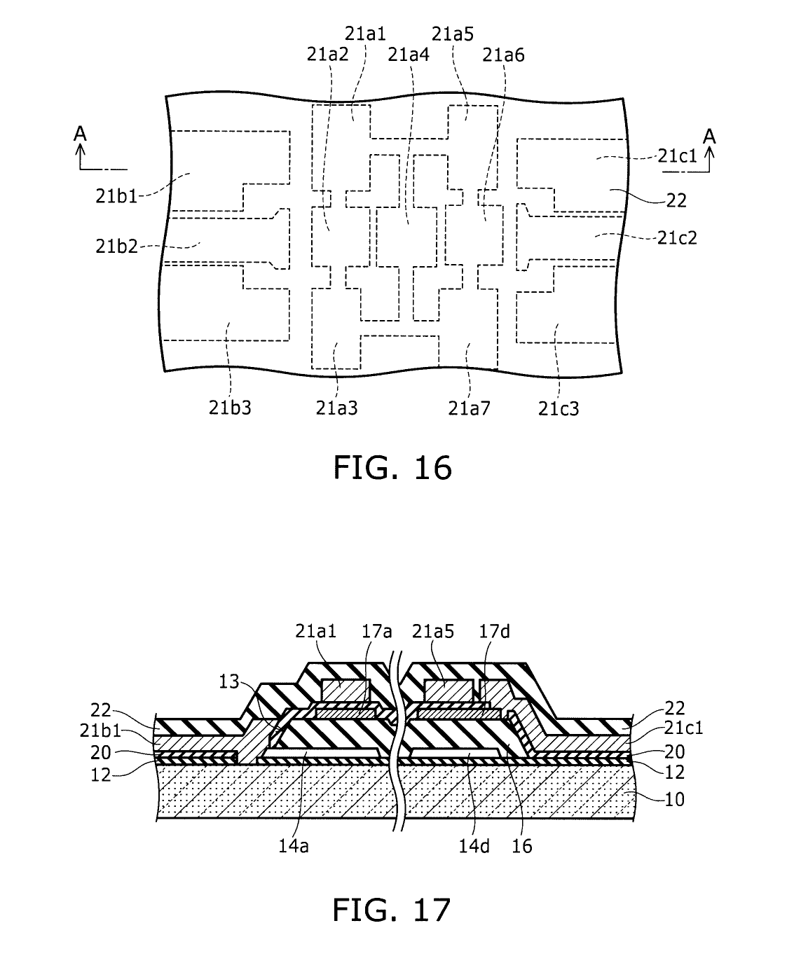

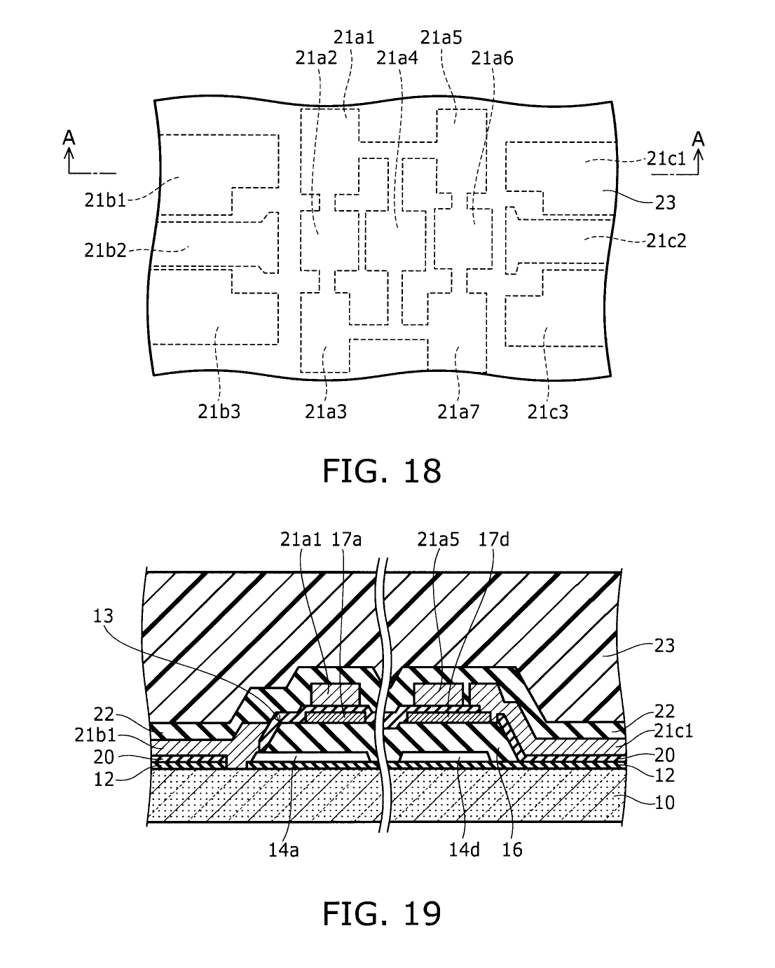

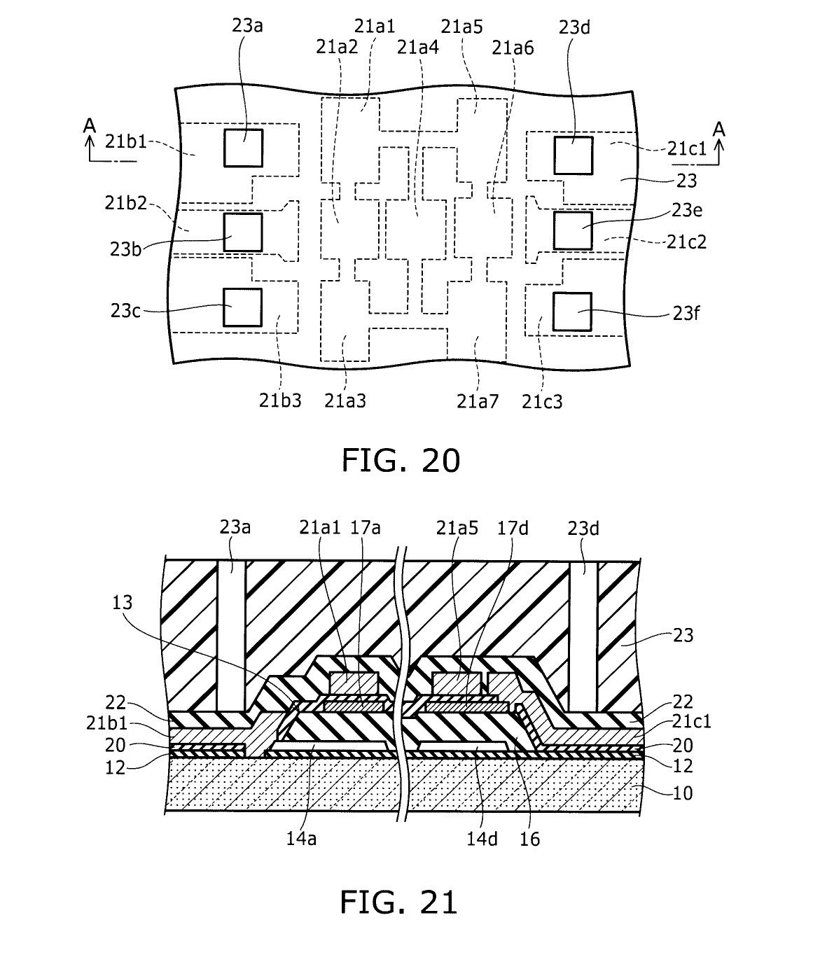

(d) As shown in FIG. 16 and FIG. 17, a cover layer 22 of Si₃N₄ is deposited by about 1 μm using CVD or the like so as to cover the extracting wirings 21b1 to 21b3, 21c1 to 21c3 and the sacrifice layers 21a1 to 21a7. And as shown in FIG. 18 and FIG. 19, after photosensitive polyimide of about 10 μm in thickness is spin coated as a resin layer 23 on the cover layer 22, the resin layer 23 is preliminarily cured. Thereafter, as shown in FIG. 21, opening patterns 23a, 23d are formed in the resin layer 23 above the extracting wirings 21b1, 21c1 by photo lithography or the like. While graphic display of the cross section is omitted, as shown in FIG. 20, opening patterns 23b, 23c, 23e, 23f are formed above extracting wirings 21b2, 21b3, 21c2, 21c3, respectively, after that the resin layer 23 is cured by heating.

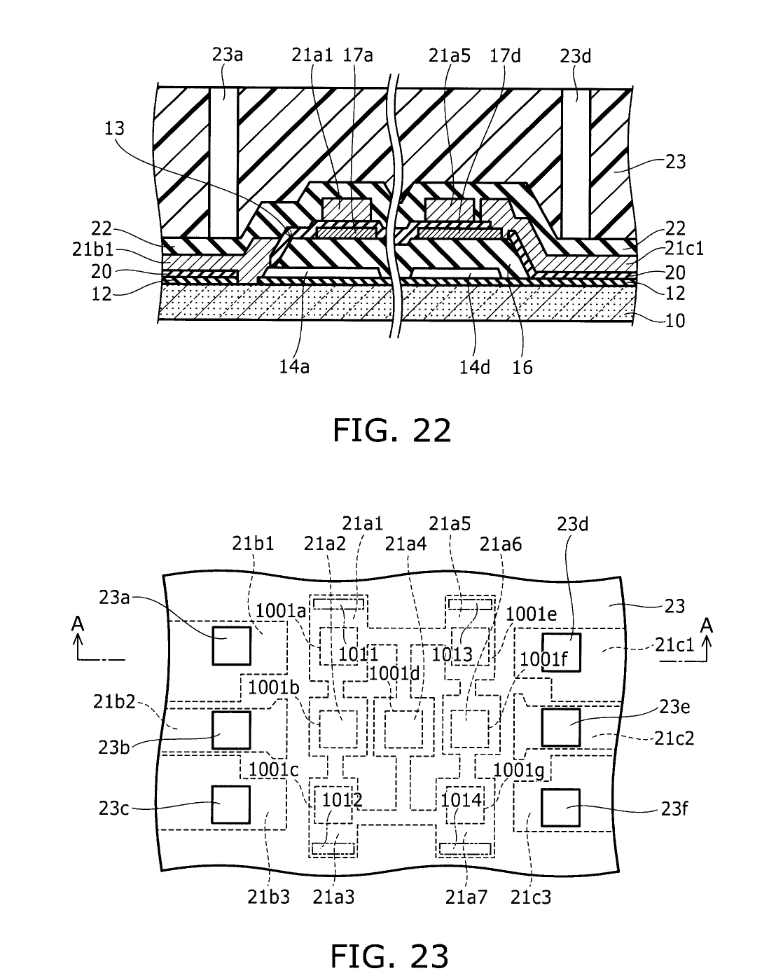

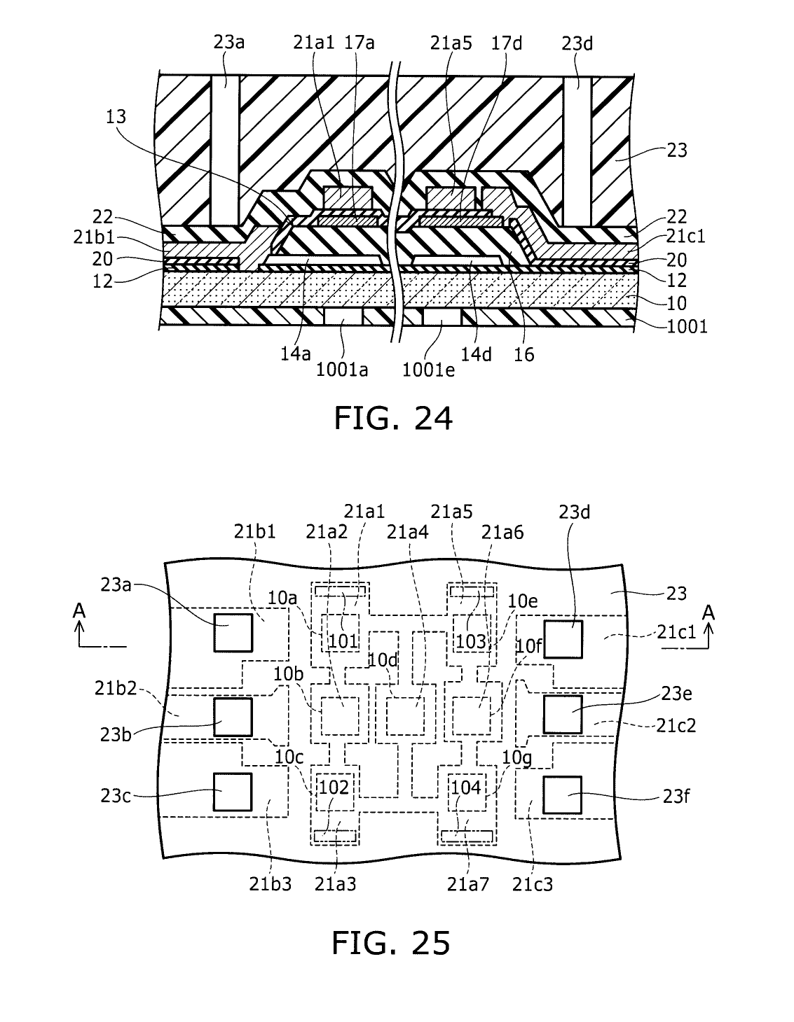

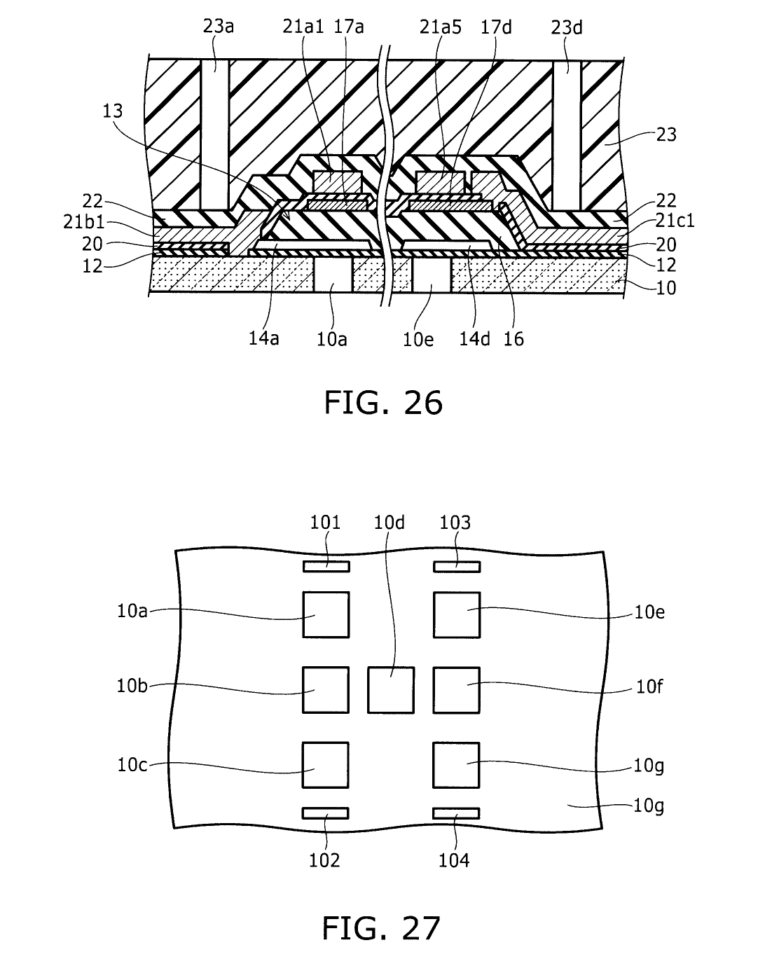

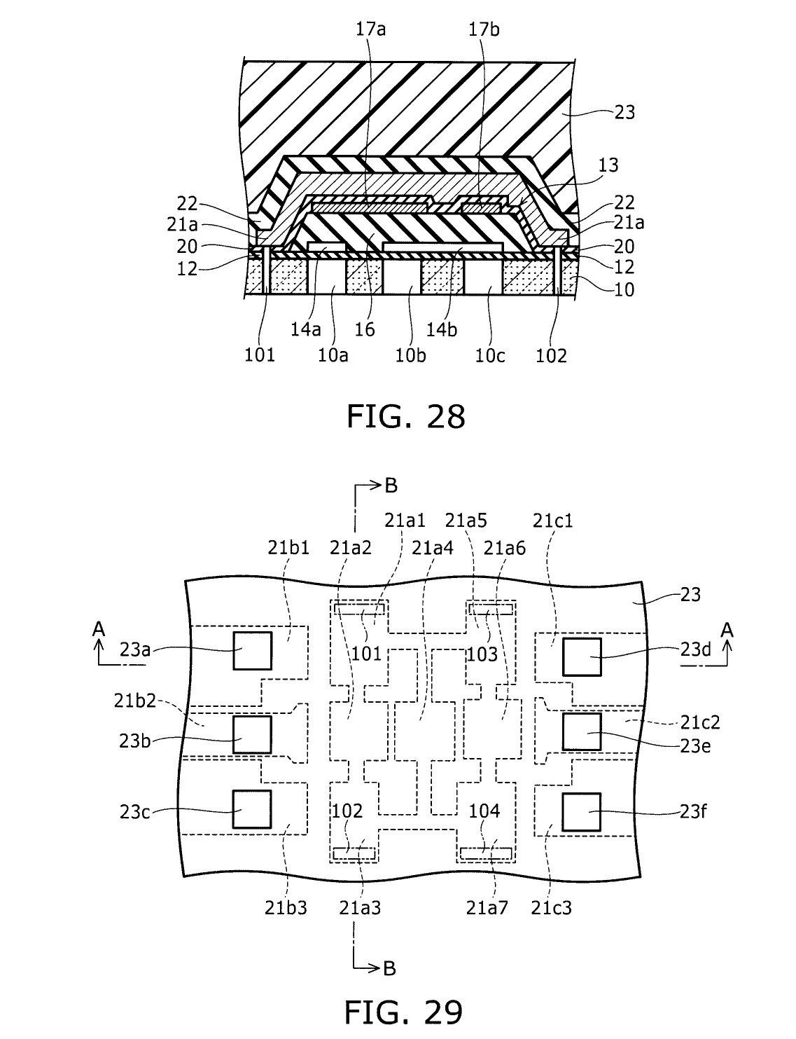

(e) As shown in FIG. 22, the backside of the substrate 10 is ground and the substrate 10 is thinned at or below about 200 μm. Thereafter, a resist film 1001 is spin coated on the backside of the substrate 10. Opening patterns 1001a, 1001e are formed at locations corresponding to sacrifice layers 21a1, 21a5, respectively by photolithography as shown in FIG. 24. While graphic display of cross sections is omitted, opening patterns 1001b, 1001c, 1001d, 1001f, 1001g are formed at locations corresponding to sacrifice layers 21a2, 21a3, 21a4, 21a6, 21a7, respectively as shown in FIG. 23. Moreover, opening aperture patterns 1011, 1012, 1013, 1014 are formed in the resist layer 1001 at locations corresponding to surroundings of sacrifice layers 21a1, 21a3, 21a5, 21a7. A part of the substrate 10 is selectively removed by RIE or the like using the resist film 1001 as an etching mask. Next, the resist film 1001 is removed as shown in FIG. 26. And opening portions 10a, 10b, 10c and 101, 102 passing through the substrate 10 are formed as shown in FIG. 28. Furthermore, the protect film 12 and the passivation film 20 exposed to the apertures 101, 102 are selectively removed as shown in FIG. 28 by photolithography and RIE or the like. While graphic display of cross sections are omitted, opening portions 10d, 10f, 10g and apertures 103, 104 passing through the substrate 10 are formed similarly as shown in FIG. 25 and FIG. 27.

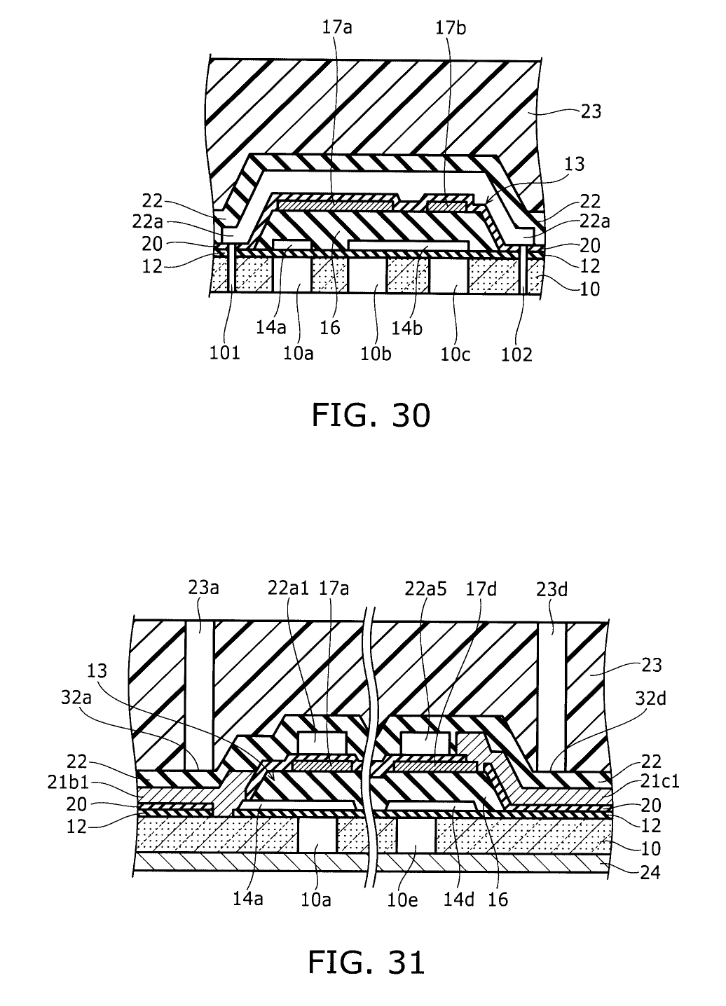

(f) Thereafter, the sacrifice layer (Al layer) 21a is selectively removed by wet etching or the like using hydrochloric acid as an etchant through the apertures 101, 102. The sacrifice layer 21a may be dry-etched using gases including chlorine as an etchant. And the cavity 22a is formed above the upper electrode wirings 17a, 17b of the resonance section 13 as shown in FIG. 30. As is clear from FIG. 29, the sacrifice layer (Al layer) 21a is also selectively removed similarly through the apertures 103, 104 not shown in the cross section of FIG. 30. While graphic display of the cross sections is omitted, as shown in FIG. 1, the cavities 22a4, 22a6, 22a7 over the upper electrode wiring 17c, and the cavity 22a5 over the upper electrode wiring 17d are formed.

(g) As shown in FIG. 31, the cover layer 22 under the opening patterns 23a, 23d of the resin layer 23 is selectively removed by RIE or the like and the electrode pad portions 32a, 32d are formed by exposing the extracting wirings 21b1, 21c1. While graphic display of cross sections is omitted, as shown in FIG. 1, the cover layer 22 under the opening patterns 23b, 23c, 23e, 23f is selectively removed and the electrode pad portions 32b, 32c, 32e, 32f are formed by exposing the extracting wirings 21b2, 21b3, 21c2, 21c3. After that, the electric characteristic and frequency of the thin film piezoelectric resonator are measured using a probe. In order to increase the resonant frequency, physical etching of a lower part of the resonance section 13 using argon (Ar) ion beam or argon plasma or the like may be used through the opening portions 10a, 10b, 10c from the lower side of the substrate 10. In order to decrease the resonant frequency, for example gold tin (AuSn) or the like may be deposited on the lower side of the resonance section 13 using sputtering or the like through the opening portions 10a, 10b, 10c from the back side of the substrate 10. Furthermore, adhesive, for example, thermosetting resin is coated on the backside of the substrate 10, the seal substrate 24 is applied to the substrate 10, and hollow sealing of the backside is conducted by hot curing and bonding. The high frequency filter shown in FIG. 1 to FIG. 3 is manufactured by the process described above.

According to the method of manufacturing the thin film piezoelectric resonator according to the embodiments described above, since the sacrifice layer 21a is removed from the backside of the substrate 10 after providing the resin layer 23 over the cover layer, the sacrifice layer can be removed without occurrence of crack and deformation of the cover layer 22. As a result, the thin film piezoelectric resonator with improved strength can be achieved.

### A First Modification Example of the Embodiment

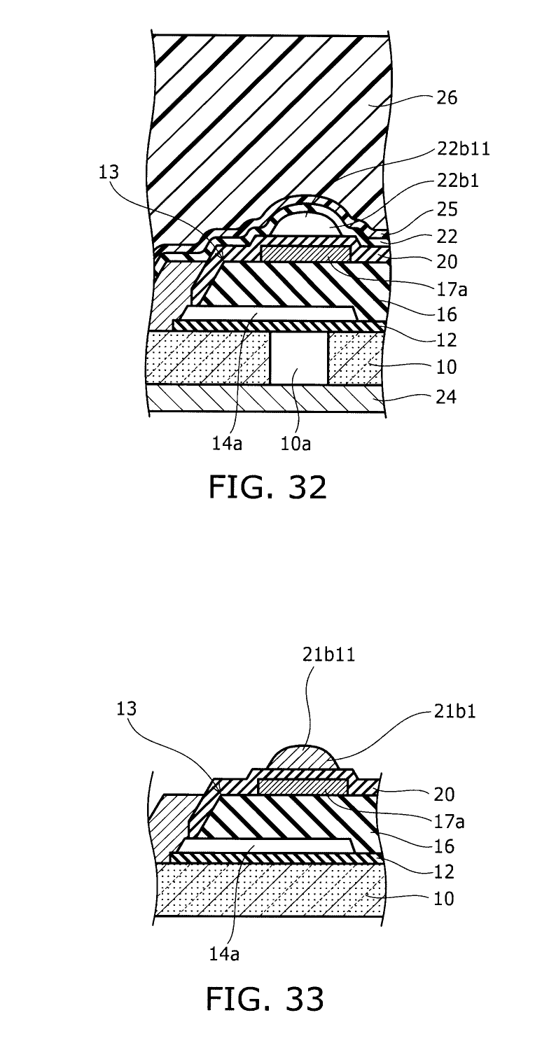

FIG. 32 shows a view enlarging a portion taking note of a thin film piezoelectric resonator 50a of the high frequency filter according to a first modification example of the invention. The thin film piezoelectric resonator 50a illustrated in FIG. 32 is formed similarly to the high frequency filter using the thin film piezoelectric resonator according to the embodiment of the invention, except providing a cavity 22b1 having a ceiling portion 22b11 being convex upward in the cross section orthogonal to the upper surface of the substrate 10, a thick thermoplastic resin layer 25 provided over the cover layer 22 and a thicker thermosetting resin layer 26 than the thermoplastic resin layer 25 provided over the thermoplastic resin layer 25. While graphic display is omitted, other thin film piezoelectric resonators 50b to 50g have the substantially similar cross sectional structure.

A variety of resin can be used as the thermoplastic resin layer 25 without special restriction as long as resins can relax stresses occurring during hot curing of the hot curing layer and does not hot cure. For example, resin such as polyamide, acrylic butadiene styrene (ABS) or the like can be used. Resin such as polyimide, permanent photo-resist or the like can be used as the thermosetting resin layer 26.

Stress can be relaxed by providing the cover layer 22 having the cavity 22b1 having the ceiling portion 22b11 being convex upward. The cover layer 22 can be strengthened by providing the thermosetting resin layer 26. Moreover, the thin film thermoplastic resin layer 25 provided as the stress relaxing layer during curing the thermosetting resin layer 26 allows the stress occurring in the post process to be relaxed. As a result, the crack and the deformation of the cover layer 22 can be more effectively prevented.

A method of manufacturing a high frequency filter using a thin film piezoelectric resonator according to a first modification example of the embodiment of the invention will be described with reference to FIG. 6 to FIG. 33: after similar processes to FIG. 6 to FIG. 15, process conditions such as photolithography and etching or the like are adjusted and a sacrifice layer 21b1 is processed so as to provide a ceiling portion 21b11 being convex upward in the cross section orthogonal to the upper surface of the substrate 10 as shown in FIG. 33. Next, the cover layer 22 is provided by processes similar to FIG. 16 and FIG. 17. And after a thermoplastic resin layer 25 is spin coated over the cover layer 22, the thermoplastic resin layer 25 is hot-cured. Furthermore, after a thermosetting resin layer 26 is spin coated over the thermoplastic resin layer 25, the thermosetting resin layer 26 is hot-cured. Thereafter, the high frequency filter shown in FIG. 32 is achieved through processes similar to FIG. 20 to FIG. 33.

### A second Modification Example of the Embodiment

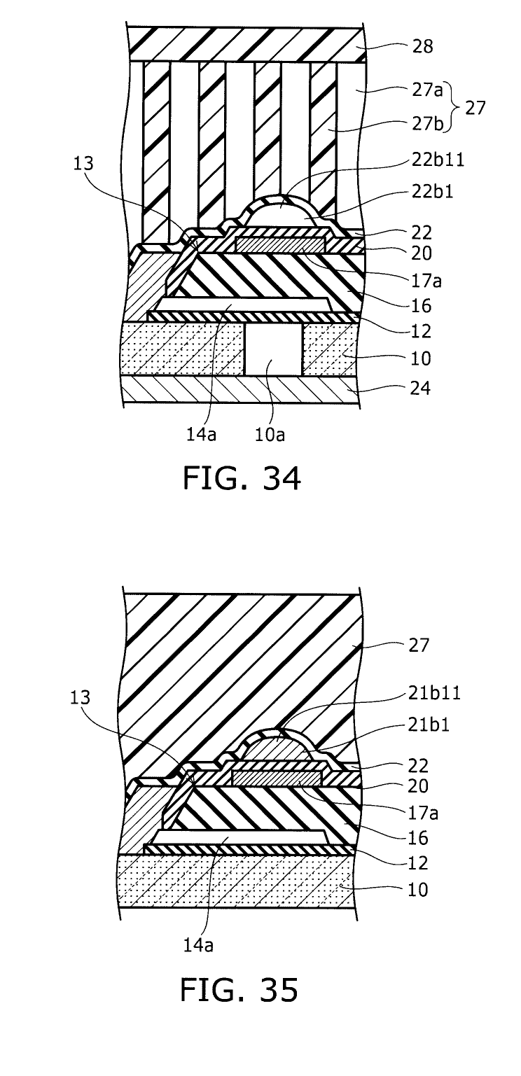

FIG. 34 shows a view enlarging a portion taking note of a thin film piezoelectric resonator 50a of the high frequency filter according to a first modification example of the invention. The thin film piezoelectric resonator 50a illustrated in FIG. 34 is formed similarly to the high frequency filter using the thin film piezoelectric resonator according to the embodiment of the invention, except providing a cavity 22b1 having a ceiling portion being convex upward in the cross section orthogonal to the upper surface of the substrate 10 and a thermosetting resin layer 27 different from the resin layer 23. The thermosetting resin layer 27 provides plural support portions 27b, an outer layer supported by the support portions 27b, and a hollow portion 27a surrounded by the support portions 27b and the outer layer 28. For example, polyimide and permanent photo-resist or the like can be used as the thermosetting resin layer 27.

Stress applied to the cover layer 22 can be relaxed by the thermosetting layer 27 of “suspension bridge configuration” as shown in FIG. 34. As a result, crack and deformation of the cover layer 22 can be effectively prevented.

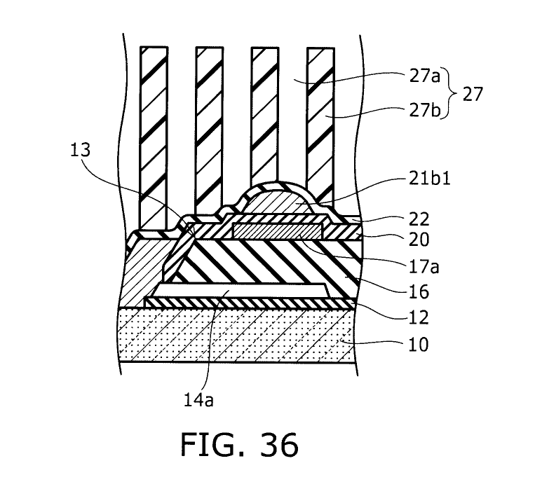

The thin film piezoelectric resonator according to the second modification example of the embodiment is manufactured as follows. As with the first modification example of the embodiment, processes similar to FIG. 6 to FIG. 15 and FIG. 33 are conducted. Next, the cover layer 22 is provided by conducting processes similar to FIG. 16 and FIG. 17. And the cover layer 22 is covered by the preliminary cured resin layer 27 and the cross sectional structure shown in FIG. 35 is formed. Thereafter, in formation of the opening portion pattern in the resin layer 27 on the extracting wiring as with FIG. 20 and FIG. 21, photolithography or the like is conducted until the cover layer 22 is exposed to the resin layer 27 over the sacrifice layer 21b1 as shown in FIG. 36, and plural support portions 27b are formed. A laminate film such as polyimide and permanent photo-resist or the like is applied to the support portions 27b as the outer layer 28 and hollow sealing is performed by hot-curing and bonding. Thereafter, the high frequency filter shown in FIG. 34 is achieved through processes similar to FIG. 22 to FIG. 33.

### Other Embodiment

Embodiments of the invention have been described above, but it should not be understood that description and figures forming a part of the disclosure limit the invention. The disclosure reveals various alternative embodiments, examples and operating technologies to a person skilled in the art. For example, Al is used for the sacrifice layer 21a and the extracting wirings 21b, 21c in embodiments, however metals such as aluminum-copper (Al—Cu), aluminum-silicon-copper (Al—Si—Cu), Mo or the like can be used other than Al.

In this manner, the invention naturally includes various embodiments not described here. Therefore, the technical scope of the invention is limited by only specified matter of the invention according to the scope of claims which is reasonable based on the above description.

1. A thin film piezoelectric resonator comprising:
a substrate having an opening portion which passes through from a top surface to a bottom surface of the substrate, and an aperture which is provided distant from the opening portion;
a resonance section having a lower electrode provided on the opening portion of the substrate, a piezoelectric film provided on the lower electrode and an upper electrode opposed to the lower electrode across the piezoelectric film;
a cover layer covering the resonance section through a cavity which is formed above the upper electrode; and
a resin layer provided on the cover layer,
the cavity being connected to the aperture.

2. The thin film piezoelectric resonator according to claim 1, wherein the resin layer includes a thermoplastic resin layer and a thermosetting resin layer provided in this order from the cover layer.

3. The thin film piezoelectric resonator according to claim 2, wherein the thermosetting resin layer is thicker than the thermoplastic resin layer.

4. The thin film piezoelectric resonator according to claim 1, wherein the resin layer includes a plurality of support portions and an outer layer which is supported by the support portions, the support portions being provided on the cover layer.

5. The thin film piezoelectric resonator according to claim 4, wherein a hollow portion surrounded by the support portions and the outer layer is provided.

6. The thin film piezoelectric resonator according to claim 5, wherein the support portions and the hollow portion are provided on the cavity.

7. A thin film piezoelectric resonator comprising:
a substrate having an opening portion which passes through from a top surface to a bottom surface of the substrate, and an aperture which is provided distant from the opening portion;
a resonance section having a lower electrode provided on the opening portion of the substrate, a piezoelectric film provided on the lower electrode and an upper electrode opposed to the lower electrode across the piezoelectric film;
a cover layer covering the resonance section through a cavity which is formed above the upper electrode; and
a resin layer provided on the cover layer,
the cavity being connected to the aperture, and the cavity having a ceiling portion being convex upward.

8. The thin film piezoelectric resonator according to claim 7, wherein the ceiling portion has a curved surface which is convex upward.

9. The thin film piezoelectric resonator according to claim 7, wherein the resin layer includes a thermoplastic resin layer and a thermosetting resin layer provided in this order from the cover layer.

10. The thin film piezoelectric resonator according to claim 9, wherein the thermosetting resin layer is thicker than the thermoplastic resin layer.

11. The thin film piezoelectric resonator according to claim 7, wherein the resin layer includes a plurality of support portions and an outer layer which is supported by the support portions, the support portions being provided on the cover layer.

12. The thin film piezoelectric resonator according to claim 11, wherein a hollow portion surrounded by the support portions and the outer layer is provided.

13. The thin film piezoelectric resonator according to claim 12, wherein the support portions and the hollow portion are provided on the cavity.

14. The thin film piezoelectric resonator according to claim 7, wherein the cover layer is made silicon nitride.

15. A method of manufacturing a thin film piezoelectric resonator, comprising:
forming a resonance section by providing a lower electrode, a piezoelectric film and an upper electrode in this order on a substrate;
forming a pattern of a sacrifice layer selectively on the upper electrode;
forming a cover layer covering the resonance section including the sacrifice layer;
forming a resin layer on the cover layer;
forming an opening portion which passes through the substrate below the lower electrode and an aperture which arrives at the sacrifice layer by passing through the substrate; and
forming a cavity above the upper electrode by introducing an etchant through the aperture.

16. The method of manufacturing a thin film piezoelectric resonator according to claim 15, wherein the cavity is formed so that the cavity has a ceiling portion which is convex upward.

17. The method of manufacturing a thin film piezoelectric resonator according to claim 16, wherein the ceiling portion has a curved surface which is convex upward.

18. The method of manufacturing a thin film piezoelectric resonator according to claim 15, wherein the resin layer includes a thermoplastic resin layer and a thermosetting resin layer provided in this order from the cover layer.

19. The method of manufacturing a thin film piezoelectric resonator according to claim 18, wherein the thermosetting resin layer is thicker than the thermoplastic resin layer.

20. The method of manufacturing a thin film piezoelectric resonator according to claim 15, further comprising:
forming a plurality of support portions by processing the resin layer; and
forming an outer layer which is supported by the support portions.
